(19) United States
(12) Patent Application Publication
(10) Pub. No.: US 2007/0276221 A1
(43) Pub. Date: Nov. 29, 2007

(54) Prescan for optimization of mri scan parameters

(75) Inventor: Jan Bertus Marten Warntjes, Eindhoven (NL)

Correspondence Address: PHILIPS INTELLECTUAL PROPERTY & STANDARDS, 595 MINER ROAD, CLEVELAND, OH, 44143, US

(73) Assignee: KONINKLIJKE PHILIPS ELECTRONICS N.V., Eindhoven (NL)

(21) Appl. No.: 10/598,665

(22) PCT Filed: Mar. 1, 2005
(86) PCT No.: PCT/IB05/50752

§ 371 Date: Sep. 7, 2006

(30) Foreign Application Priority Data
Mar. 12, 2004 (EP) 04101033.1

(51) Int. Cl. G01R 33/54

(52) U.S. Cl. 600/410

(57) ABSTRACT

The invention relates to a method and apparatus for generating magnetic resonance images. In order to achieve high quality magnetic resonance imaging combined with a user-friendly operating of a magnetic resonance apparatus it is proposed to use data obtained from a reference scan comprising SENCE reference data to determine an optimum scan parameter set taking into account a chosen target value of a specific scan parameter such as the scan time or the signal-to-noise ratio. Based on the reference scan, image noise is predicted for various sets of scan parameters (alternative use of SENCE or intrinsic foldover without SENCE; various orientations of the phase encoding direction within the slice plane). An optimum scan parameter set is determined (shortest scan time to match target SNR or hightest SNR to match target scan time).

The invention relates to a method and apparatus for generating magnetic resonance images.

In order to obtain high quality magnetic resonance images a large number of variable parameters have to be set prior to the magnetic resonance scan. Besides the normal examination parameters like sequence, contrast, resolution etc. an operator of an magnetic resonance apparatus has to choose a field of view on each slice, depending on the size of the subject to be scanned, the orientation of the slice and the region of interest within each slice. Additionally an experienced operator can minimize scan time by optimizing a number of image parameters. He may for example choose the phase encoding direction in the direction of the minimum subject diameter within the slice and adjust the rectangular field of view percentage or (R)FOV to closely encompass the subject. He may further make use of intrinsic foldover by choosing the (R)FOV even smaller than the subject size with the foldover signal remaining outside the region of interest. Finally he may make use of SENSitivity Encoding or SENSE, a parallel magnetic resonance imaging technique using multi-element synergy coils (phase-array coils). However, SENSE cannot be combined with intrinsic foldover hence for SENSE the field of view must encompass the whole subject in the phase encoding direction in the slice. Furthermore it is not clear beforehand, which of the two methods, intrinsic foldover or SENSE, is faster. To obtain high quality results it must be checked additionally which method has the best signal-to-noise ratio.

The precise tuning of (R)FOV, intrinsic foldover and SENSE is a time consuming task. Therefore in the past this planning was mostly done quite cursorily resulting in non-optimal scanning results. Furthermore, because optimizing these variables requires a skilled operator, in some cases the results are not optimal because of an unexperienced operator.

In US patent application 2002/0087066 A1 a method for generating magnetic resonance images is disclosed. Therein optimum settings of sequence parameters are determined by a control system comprising a processor and a database. Subject-specific parameters, e.g. mass, height or proton density of a subject to be examined, and examination-specific parameters, e.g. sequence type, contrast preselection or region to be imaged, are supplied to the control system. In the database subject-specific parameters, examination-specific parameters and sequence parameters obtained from prior examinations are stored linked to each other. According to the supplied subject-specific and examination-specific parameters the control system selects the appropriate sequence parameter from the parameters stored in the database. Thereby it is disadvantageous that the quality of the selected sequence parameters depends completely on the quantity and quality of data stored in the database.

It is an object of the present invention to achieve high quality magnetic resonance imaging combined with a user-friendly operating of a magnetic resonance apparatus.

This object is achieved according to the invention by a method for generating magnetic resonance images using a magnetic resonance apparatus, the method comprising the steps of acquiring a reference scan, providing the magnetic resonance apparatus with a target value of a specific scan parameter, and determining, by the magnetic resonance apparatus and based on reference scan data, an optimum scan parameter set according to the target value of the specific scan parameter.

The object of the present invention is also achieved by an apparatus for generating magnetic resonance images comprising an acquisition device for acquiring a reference scan, an operating device for providing the apparatus with a target value of a specific scan parameter, and a control device for determining, based on reference scan data, an optimum scan parameter set according to the target value of the specific scan parameter.

The magnetic resonance apparatus include inter alia coils for creation of gradient magnetic fields, current supply devices, high frequency generators, control devices, RF signal antennae, readout devices etc. All appliances are adapted to carry out the method according to the present invention. All devices, e.g. the acquisition device, the operating device and the control device, are constructed and programmed in a way that the procedures for obtaining data and for data processing run in accordance with the method of the invention.

The object of the present invention is also achieved by a computer program comprising computer instructions adapted to perform the method according to the invention when the computer program is executed in a computer. The technical effects necessary according to the invention can thus be realized on the basis of the instructions of the computer program in accordance with the invention. Such a computer program can be stored on a carrier such as a CD-ROM or it can be available over the internet or another computer network. Prior to executing the computer program is loaded into the computer by reading the computer program from the carrier, for example by means of a CD-ROM player, or from the internet, and storing it in the memory of the computer. The computer includes inter alia a central processor unit (CPU), a bus system, memory means, e.g. RAM or ROM, storage means, e.g. floppy disk or hard disk units and input/output units. Preferably the computer is an integral component of the magnetic resonance apparatus.

The present invention enables a high quality magnetic resonance imaging, because an optimum scan parameter set is determined automatically by the magnetic resonance apparatus. Human error can be much reduced. Moreover the operating of the magnetic resonance apparatus is user-friendly, because merely a target value of a specific scan parameter has to be provided. This can be done easily even by an unexperienced operator. The optimum scan parameter set is determined solely by using data already available after a reference scan. Because such reference scans are acquired by default, there are no additional tasks necessary compared to known techniques. In other words, data already available is used for enhancing and optimizing the magnetic resonance imaging procedure. As a further result the subject to be examined will not unnecessarily be exposed to high radiofrequency magnetic fields.

These and other aspects of the invention will be further elaborated on the basis of the following embodiments which are defined in the dependent claims.

In a preferred embodiment of the invention the reference scan data include sensitivity data for each coil element of the magnetic resonance apparatus for each voxel. In other words, during the reference scan a three-dimensional volume coil sensitivity map of the whole subject is obtained of both the system body coil and all coil elements within the imaging volume. Preferably a SENSE reference scan according to the standard protocol is used. With this scan all sensitivity data for the magnetic resonance apparatus is obtained. There is no need for further image acquisition to obtain views in other orientations.

In another embodiment of the present invention the optimum scan parameter set is determined for a defined region of interest. In other words a region of interest scanning is carried out. For this purpose the operator indicates an arbitrary shaped region of interest within a particular slice of the subject to be scanned. In order to provide the required image data to the operator a survey scan may be carried out.

In a further embodiment of the invention the specific scan parameter is the scan time. In other words, a desired scan time, e.g. 20 seconds, is provided to the magnetic resonance apparatus as a target value. The magnetic resonance apparatus now determines an optimum scan parameter set meeting this specification. In yet another preferred embodiment of the invention the specific scan parameter is the signal-to-noise ratio. In this case the magnetic resonance apparatus determines an optimum scan parameter set meeting this specified signal-to-noise ratio. Other specific scan parameters can be used as well.

The determination of the optimum scan parameter set preferably comprises determining the value of the specific scan parameter for a number of predetermined scan parameter sets. Thereby the predetermined scan parameter sets preferably include sets with different orientations of the phase encode direction. In another embodiment the predetermined scan parameter sets include sets with different (R)FOV. It is also advantageous to combine a number of sets with different orientations of the phase encode direction and a number of sets with different (R)FOV. An additional parameter is the usage of SENSE. Therewith it is possible to determine the optimum scan parameter set taking into account a plurality of different parameter combinations.

Preferably the actual scanning of the subject is finally performed automatically using the determined optimum scan parameter set. Besides the providing of the target value of the specific scan parameter no further interaction of the operator is necessary in this case. The final scan image will be obtained without the operator knowing the field of view, the (R)FOV, the phase encoding direction or the usage of SENSE.

These and other aspects of the invention will be described in detail hereinafter, by way of example, with reference to the following embodiments and the accompanying drawings; in which:

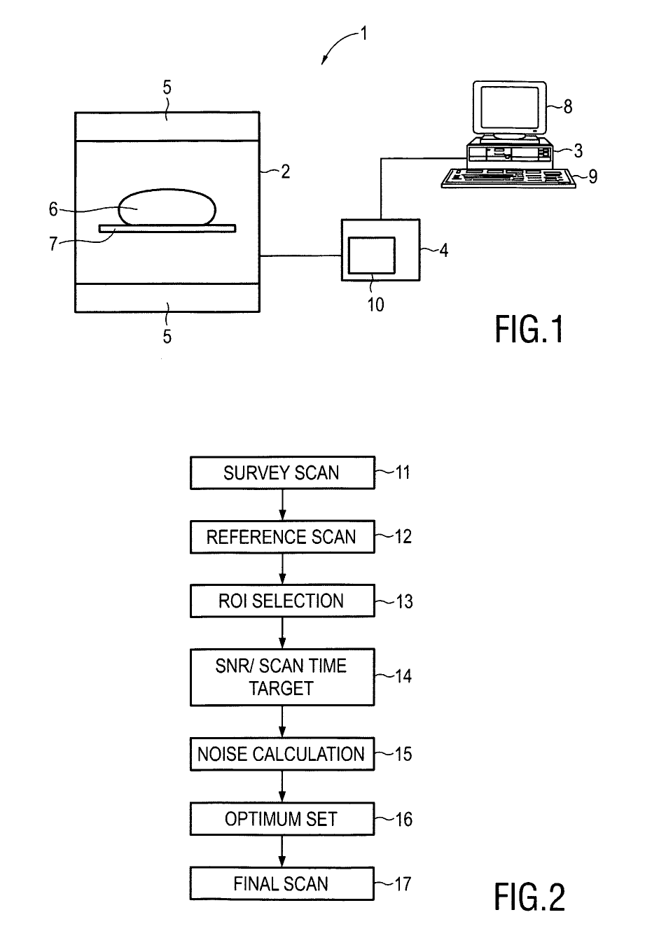

FIG. 1 is a block diagram showing the apparatus according to the invention;

FIG. 2 is a flow chart showing the steps for carrying out the method according to the invention.

A magnetic resonance apparatus on which the preferred embodiment can be implemented is shown in a simplified block diagram of FIG. 1. The apparatus 1 basically comprises an acquisition device 2, an operating device 3 and a control device 4 connecting acquisition device 2 and control device 4. The acquisition device 2 is adapted for acquiring magnetic resonance scans including survey scans and reference scans. It includes inter alia coils 5 for creation of gradient magnetic fields, RF signal antennae, readout devices, current supply devices, high frequency generators etc. A subject 6 is placed within the magnet on a subject table 7. The operating device 3 is adapted for providing the apparatus with a target value of a specific scan parameter. It includes a computer console with input and output devices, e.g. a computer monitor 8 and a keyboard 9. Other input devices, e.g. touch screen or mouse might be used as well. The control device 4 is adapted for determining the optimum scan parameter set and for controlling the acquisition device 2. It includes a computer 10 including CPU, memory and storage means etc. for calculating the image noise and determining the optimum scan parameter set. For this purpose the computer 10 comprises a computer program adapted to perform the inventive method.

In FIG. 2 a flow chart diagram shows the steps for carrying out the invention. After the subject 6 to be examined has been positioned on the subject table 7 a survey scan is performed in a first step 11. This standard survey scan consist e.g. of a combination of sagittal, coronal and transversal images for a quick determination of the location and size of the subject 6.

After the survey scan, which takes only a few seconds, a standard three-dimensional volume SENSE reference scan is started automatically in a second step 12. The reference volume of imaging is adjusted to the subject size found with a signal threshold measurement on the survey images. By adjusting automatically the reference volume of imaging the highest resolution is obtained in the reference scan time.

In the next step 13 the operator of the operating device 3 indicates a particular region of interest on the survey image, e.g. using a pointing device such as a computer mouse. In a first embodiment of the invention the operator now indicates a desired signal-to-noise ratio in a next step 14. In a subsequent step 15 the control device 4 then calculates the expected noise of the image using a number of different predetermined scan parameter sets. Subsequently the optimum scan parameter set, that is the scan parameter set with the shortest scan time to match the target signal-to-noise ratio, is automatically determined by the control device 4 in step 16. Finally scanning of the subject 6 is performed automatically by the acquisition device 2 using the determined optimum scan parameter set in step 17.

Additionally the operator device 3 may be adapted to also accept detailed manual instructions from the operator. This can be accomplished by defining a corresponding user interface underneath the easy-to-use shell. Therewith in addition to the easy-to-use operation a very flexible operation of the magnetic resonance apparatus 1 is possible also. In this case the optimum scan parameter set may be presented to the operator, e.g. in form of a graphical or textual feedback. An experienced operator may then based on the optimum scan parameter set individually tune each single scan parameter according to his best knowledge.

In a second embodiment of the invention in step 14 the operator indicates by means of the operating device 3 a desired scan time instead of a signal-to-noise ratio. The control device 4 again calculates the expected noise of the image using a number of different predetermined scan parameter sets in step 15. Afterwards the optimum scan parameter set, that is the scan parameter set with the highest signal-to-noise ratio to match the target scan time, is automatically determined by the control device 4 in step 16. Scanning of the subject 6 is finally performed in step 17 by the acquisition device 2 using the determined optimum scan parameter set.

The value of the image noise is calculated in step 15 by the control device 4 for twelve different predetermined sets of scan parameters. These predetermined sets are divided into two subsets, each subset describing six orientations of the phase encode direction rotated 30 degrees with respect to each other in the slice plane. The first subset is characterized by an (R)FOV chosen such that the intrinsic foldover signal falls outside the region of interest. The second subset is characterized by the use of SENSE with the (R)FOV chosen such that it encompasses the subject size. The SENSE reduction factor is chosen according to the target scan time. Other predetermined scan parameter sets may be used accordingly.

In other words, in step 15 the control device 4 predicts the noise of the twelve images without the need of any further test scans. Thereby the resolution of these images can be very low, e.g. in the order of 1 cm² pixels, since the sensitivity does not change much per centimeter. Then the optimum scan parameter set is determined in step 16 by the control device 4. All calculating can be carried out during a very short time period. Therefore the actual magnetic resonance scan of the subject 6 in step 17 can be started virtually instantaneous after the target value has been provided to the operating device 3.

The noise of each image is calculated in step 15 using the sensitivity matrices obtained from the three-dimensional reference scan before the actual imaging. In other words the reference data is reused for optimizing the scan parameter of the actual magnetic resonance scan of the subject 6. The signal value p̅ of an image pixel is calculated according to:
p̅=(S^{H}Ψ⁻¹S)⁻¹S^{H}Ψ⁻¹ m̅
wherein S is the sensitivity matrix, Ψ is the noise correlation matrix and m̅ is the measurement data of all coil elements 5.

In a real experiment there is noise n̅ in the measurement data, where the mean value of the noise is zero and the mean value of the noise squared is the noise variance σ².

The noise in the measurement data m̅ leads to noise in the signal value p̅ according to:
\overline{\hat{p}}=(S^{H}Ψ⁻¹S)⁻¹S^{H}Ψ⁻¹( m̅+ n̅)= p̅+(S^{H}Ψ⁻¹S)⁻¹S^{H}Ψ⁻¹ n̅

The mean difference between the signal value with noise \overline{\hat{p}} and the signal value without noise p̅ is zero, the mean difference between the signal value with noise \overline{\hat{p}} and the signal value without noise p̅ squared is, again, the noise variance σ².

The noise variance is calculated based on the reference image sensitivity matrices according to:

$$\begin{matrix} {σ}^{2} = 〈 {\vert {p}^{\hat{\_}} - \overline{p} \vert}^{2} 〉 = 〈 ( {p}^{\hat{\_}} - \overline{p} ) {( {p}^{\hat{\_}} - \overline{p} )}^{H} 〉 \\ = 〈 ( {( {S}^{H} {Ψ}^{- 1} S )}^{- 1} {S}^{H} {Ψ}^{- 1} \overline{n} ) {( {( {S}^{H} {Ψ}^{- 1} S )}^{- 1} {S}^{H} {Ψ}^{- 1} \overline{n} )}^{H} 〉 \\ = 〈 {( {S}^{H} {Ψ}^{- 1} S )}^{- 1} {S}^{H} {Ψ}^{- 1} \overline{n} {\overline{n}}^{H} {Ψ}^{- 1} {S ( {S}^{H} {Ψ}^{- 1} S )}^{- 1} 〉 \\ = 〈 {( {S}^{H} {Ψ}^{- 1} S )}^{- 1} {S}^{H} {Ψ}^{- 1} Ψ {Ψ}^{- 1} {S ( {S}^{H} {Ψ}^{- 1} S )}^{- 1} 〉 \\ = 〈 {( {S}^{H} {Ψ}^{- 1} S )}^{- 1} 〉\end{matrix}$$

In other words for each pixel in an image the noise standard deviation can be predicted according to:
σ=\sqrt{(S^{H}Ψ⁻¹S)_{ρρ}⁻¹}

For the typical noise of an image the mean noise standard deviation or the maximum noise standard deviation is used in step 15.

It will be evident to those skilled in the art that the invention is not limited to the details of the foregoing illustrative embodiments, and that the present invention may be embodied in other specific forms without departing from the spirit or essential attributes thereof. The present embodiments are therefore to be considered in all respects as illustrative and not restrictive, the scope of the invention being indicated by the appended claims rather than by the foregoing description, and all changes which come within the meaning and range of equivalency of the claims are therefore intended to be embraced therein. It will furthermore be evident that the word “comprising” does not exclude other elements or steps, that the words “a” or “an” does not exclude a plurality, and that a single element, such as a computer system or another unit may fulfill the functions of several means recited in the claims. Any reference signs in the claims shall not be construed as limiting the claim concerned.

1. A method for generating magnetic resonance images using a magnetic resonance apparatus, the method comprising the steps:
acquiring a reference scan,
providing the magnetic resonance apparatus with a target value of a specific scan parameter, and
determining, by the magnetic resonance apparatus and based on reference scan data, an optimum scan parameter set according to the target value of the specific scan parameter.

2. The method as claimed in claim 1, wherein the reference scan data include sensitivity data for each coil element of the magnetic resonance apparatus for each voxel.

3. The method as claimed in claim 1, wherein the optimum scan parameter set is determined for a defined region of interest.

4. The method as claimed in claim 1, wherein the specific scan parameter is the scan time.

5. The method as claimed in claim 1, wherein the specific scan parameter is the signal-to-noise ratio.

6. The method as claimed in claim 1, wherein the determining of the optimum scan parameter set comprises the step:
determining the image noise for a number of predetermined scan parameter sets.

7. The method as claimed in claim 6, wherein the predetermined scan parameter sets include sets with different orientations of the phase encode direction.

8. The method as claimed in claim 6, wherein the predetermined scan parameter sets include sets with different RFOV.

9. The method as claimed in claim 1, comprising the further step:
automatically performing a scan using the determined optimum scan parameter set.

10. An apparatus for generating magnetic resonance images comprising:
an acquisition device for acquiring a reference scan,
an operating device for providing the apparatus with a target value of a specific scan parameter, and
a control device for determining, based on reference scan data, an optimum scan parameter set according to the target value of the specific scan parameter.

11. A computer program for generating magnetic resonance images using a magnetic resonance apparatus comprising:
computer instructions to acquire a reference scan,
computer instructions to provide the magnetic resonance apparatus with a target value of a specific scan parameter)
computer instructions to determine, based on reference scan data, an optimum scan parameter set according to the target value of the specific scan parameter, when the computer program is executed in a computer.
